(19) United States
(12) Patent Application Publication
(10) Pub. No.: US 2009/0091003 A1
(43) Pub. Date: Apr. 9, 2009

(54) INSULATOR UNDERGOING ABRUPT METAL-INSULATOR TRANSITION, METHOD OF MANUFACTURING THE INSULATOR, AND DEVICE USING THE INSULATOR

(75) Inventors: Jung Wook Lim, Daejeon-city (KR); Sun Jin Yun, Daejeon-city (KR); Hyun Tak Kim, Daejeon-city (KR); Byung Gyu Chae, Daejeon-city (KR); Bong Jun Kim, Daejeon-city (KR); Kwang-Yong Kang, Daejeon-city (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Electronics and Telecommunications Research, Daejeon-ciy (KR)

(21) Appl. No.: 12/089,778

(22) PCT Filed: Oct. 16, 2006
(86) PCT No.: PCT/KR2006/004228

§ 371 Date: Apr. 10, 2008

(30) Foreign Application Priority Data
Oct. 19, 2005 (KR) 1020050098695
Feb. 23, 2006 (KR) 1020060017888

(51) Int. Cl. H01L 29/51; B05D 5/12; C23C 14/34; H05H 1/24

(52) U.S. Cl. 257/635; 428/702; 427/126.3; 427/569; 204/192.22; 257/E29.165

(57) ABSTRACT

Provided are an insulator that has an energy band gap of 2 eV or more and undergoes an abrupt MIT without undergoing a structural change, a method of manufacturing the insulator, and a device using the insulator. The insulator is abruptly transitioned from an insulator phase into a metal phase by an energy change between electrons without undergoing a structural change.

### TECHNICAL FIELD

The present invention relates to an insulator undergoing an abrupt metal-insulator transition (MIT), a method of manufacturing the insulator, and a device using the insulator, and more particularly, to an insulator having an energy band gap of 2 eV or more and undergoing an abrupt MIT, a method of manufacturing the insulator, and a device using the insulator.

### BACKGROUND ART

It has been reported that a metal-insulator transition (MIT) occurs in a Mott insulator and a Hubbard insulator. The Hubbard insulator undergoes continuous MIT. A field effect transistor using the Hubbard insulator as a channel layer has been disclosed in the Paper [Appl. Phys. Lett. 73, 1998, p 780, D. M Newns et al.]. Since the Hubbard insulator undergoes continuous MIT, electric charge, used as carriers, must be continuously added until the insulator exhibits desired metallic properties. A continuous MIT is called a second transition.

To address this problem, a Mott insulator undergoing an abrupt MIT has been disclosed in the Paper [NATO Science Series Vol II/67 (Kluwer, 2002) p 137 author: Hyun-Tak Kim] or at http://xxx.1an1.gow/abs/cond-mat/0110112. According to the Paper, the Mott insulator with a metallic bond electron structure abruptly transitions from an insulator into a metal due to an energy change between electrons. The energy changes between electrons can be caused by an externally applied change in temperature, pressure or electric field. For example, when a low-concentration of holes are added to the Mott insulator, the Mott insulator abruptly transitions from an insulator into a metal. An abrupt MIT is called a first transition.

An MIT phenomenon has also been found in LaTiO₃, YTiO₃, BaTiO₃, or a cuprate compound (e.g., YPBCO (Y₁₋ₓPrₓBaCuO_{7-δ}) with a Perovskite structure. Also, the first transition in LixCoO₂ has been disclosed in Nature Materials Volume 3 pp 627-631 [C. A. Marianetti et al., Massachusetts Institute of Technology].

However, the above materials undergo a structural change when undergoing an abrupt MIT. The MIT accompanied by the structural change has many limitations because it cannot provide a high switching speed due to positional change of atoms caused by the structural change.

However, in Applied Physics Letters Vol. 86, p 24221, Hyun-Tak Kim et al. have recently announced an abrupt MIT that is not accompanied by a structural change when an electric field is applied to VO₂. However, materials that experience an abrupt MIT without undergoing a structural change are known to have an energy band gap of 2 eV or less. This energy band gap restricts selection possibilities of materials undergoing an abrupt MIT.

### DISCLOSURE OF INVENTION

### Technical Problem

The present invention provides an insulator that has an energy band gap of 2 eV or more and undergoes an abrupt MIT without undergoing a structural change.

The present invention also provides a device using the above insulator.

The present invention also provides a method of manufacturing the above insulator.

### Technical Solution

According to an aspect of the present invention, there is provided an insulator having an energy band gap of 2 eV or more and undergoing an abrupt MIT, the insulator being abruptly changed from an insulator phase into a metal phase by an energy change between electrons without undergoing a structural change. The energy change may be caused by a change in temperature, pressure, and electric field externally applied.

The insulator may be one selected from the group consisting of an Al oxide, a Ti oxide, an oxide of an Al—Ti alloy, and a combination thereof. Alternatively, the insulator may be at least two selected from the group consisting of Al₂O₃, TiO₂, AlₓTi₁₋ₓO_{y} (0≦x≦1, 1≦y≦2), and a combination thereof.

According to another aspect of the present invention, there is provided a device including: a substrate; at least one layer of insulator thin film formed on the substrate, the insulator thin film having an energy band gap of 2 eV or more, undergoing an abrupt MIT, and abruptly changing from an insulator phase into a metal phase by an energy change between electrons without undergoing a structural change; and at least two electrodes spaced apart from each other and contacting the insulator thin film.

The energy change may be caused by a change in temperature, pressure, and electric field externally applied.

The insulator may be one selected from the group consisting of an Al oxide, a Ti oxide, an oxide of an Al—Ti alloy, and a combination thereof. Alternatively, the insulator may be one selected from the group consisting of Al₂O₃, TiO₂, AlₓTi₁₋ₓO_{y} (0<x<1, 1≦y≦2), and a combination thereof.

According to another aspect of the present invention, there is provided a method of manufacturing an insulator undergoing an abrupt MIT, the method including forming at least one layer of insulator having an energy band gap of 2 eV or more and abruptly changing from an insulator phase into a metal phase by an energy change between electrons without undergoing a structural change.

The insulator may be formed in thin film by sputtering, chemical vapor deposition, atomic layer deposition, plasma-enhanced atomic layer deposition, a pulsed laser process, or an anodizing process. The insulator may be formed in thin film by atomic layer deposition or plasma-enhanced atomic layer deposition.

The insulator may be at least one selected from the group consisting of an Al oxide, a Ti oxide, and AlₓTi₁₋ₓO_{y} (0<x<1, 1≦y≦2).

The Al precursor used to form the Al oxide and the AlₓTi₁₋ₓO_{y} (0<x<1, 1≦y≦2) may be at least one Al-based compound selected from the group consisting of an organic metal compound including alkoxide and amine and an inorganic metal compound including halide and bromine. The Ti precursor used to form the Ti oxide and the AlₓTi₁₋ₓO_{y} (0<x<1, 1≦y≦2) may be at least one Ti-based compound selected from the group consisting of an organic metal compound including alkoxide and amine and an inorganic metal compound including halide and bromine. The oxygen-precursor used to form the Al oxide, the Ti oxide and the AlₓTi₁₋ₓO_{y} (0<x<1, 1≦y≦2) may be one selected from the group consisting of oxygen, H₂O, hydrogen peroxide, and a mixture thereof.

The forming of the Al oxide thin film may include: loading a substrate into a chamber; injecting Al precursor vapor into the chamber to form an absorption material on an upper surface of the substrate by surface saturation absorption; purging the chamber to remove any remaining unabsorbed Al precursor vapor; and injecting an oxygen-precursor into the chamber to form the Al oxide thin film by surface saturation reaction with the absorption material.

The forming of the Ti oxide thin film may include: loading a substrate into a chamber; injecting Ti precursor vapor into the chamber to form an absorption material on an upper surface of the substrate by surface saturation absorption; purging the chamber to remove any remaining unabsorbed Ti precursor vapor; and injecting an oxygen-precursor into the chamber to form the Ti oxide thin film by surface saturation reaction with the absorption material.

The forming of the AlₓTi₁₋ₓO_{y} (0<x<1, 1≦y≦2) thin film may include: loading a substrate into a chamber; injecting Al precursor vapor into the chamber to form a first absorption material on an upper surface of the substrate by surface saturation absorption; purging the chamber to remove any remaining unabsorbed Al precursor vapor; injecting an oxygen-precursor into the chamber to form the Al oxide thin film by surface saturation reaction with the first absorption material; injecting Ti precursor vapor into the chamber to form a second absorption material on an upper surface of the Al oxide thin film by surface saturation absorption; purging the chamber to remove any remaining unabsorbed Ti precursor vapor; and injecting an oxygen-precursor into the chamber to form the Ti oxide thin film by surface saturation reaction with the second absorption material, wherein the forming of the Al oxide thin film and the forming of the Ti oxide thin film are repeatedly performed according to the composition ratio of the AlₓTi₁₋ₓO_{y} (0<x<1, 1≦y≦2) thin film.

The ratio of the number of times of repetition of the forming the Al oxide thin film to the number of times of repetition of the forming the Ti oxide thin film may be one of 1:1, 1:2, 1:3, 1:4, and 1:5.

The oxygen-precursor may be in a plasma state.

The forming of the AlₓTi₁₋ₓO_{y} (0<x<1, 1≦y≦2) thin film may include: loading a substrate into a chamber; injecting Al precursor vapor into the chamber to form a first absorption material on an upper surface of the substrate by surface saturation absorption; purging the chamber to remove any remaining unabsorbed Al precursor vapor; injecting an oxygen-precursor into the chamber and forming the Al oxide thin film with a thickness of 1-1,000 nm by repetition of surface saturation reaction with the first absorption material; injecting Ti precursor vapor into the chamber to form a second absorption material on an upper surface of the Al oxide thin film by surface saturation absorption; purging the chamber to remove any remaining unabsorbed Ti precursor vapor; and injecting an oxygen-precursor into the chamber and forming the Ti oxide thin film with a thickness of 1-1,000 nm by repetition of surface saturation reaction with the second absorption material, wherein the Al oxide thin film and the Ti oxide thin film are alternately and repeatedly deposited.

### DESCRIPTION OF DRAWINGS

The above and other features and advantages of the present invention will become more apparent by describing in detail exemplary embodiments thereof with reference to the attached drawings in which:

FIG. 1 is a graph illustrating a current-to-voltage relationship of an AlₓTi₁₋ₓO_{y} thin film according to an embodiment of the present invention;

FIG. 2 is a cross-sectional view of a first switching device using the AlₓTi₁₋ₓO_{y} thin film having an energy band gap of 2 eV or more, wherein the first switching device is configured as a horizontal-structure two-terminal switching device, according to an embodiment of the present invention;

FIG. 3 is a cross-sectional view of a second switching device using the AlₓTi₁₋ₓO_{y} thin film having an energy band gap of 2 eV or more wherein the second switching device is configured as a vertical-structure two-terminal switching device, according to another embodiment of the present invention; and

FIG. 4 is a cross-sectional view of a third switching device using the AlₓTi₁₋ₓO_{y} thin film having an energy band gap of 2 eV or more wherein the third switching device is configured using a stack of devices similar to the second switching device illustrated in FIG. 3, according to an embodiment of the present invention

### BEST MODE

The present invention will now be described more fully with reference to the accompanying drawings, in which exemplary embodiments of the invention are shown. The invention may, however, be embodied in many different forms and should not be construed as being limited to the embodiments set forth herein; rather, these embodiments are provided so that this disclosure will be thorough and complete, and will fully convey the concept of the invention to those skilled in the art. Like reference numerals in the drawings denote like elements, and thus their description will be omitted.

Embodiments of the present invention provide a material that undergoes an abrupt metal-insulator transition (MIT) and have an energy band gap of 2 eV or more without undergoing a structural change. AlₓTi₁₋ₓO_{y} (0≦x≦1, 1≦y≦2) is provided as an example of the above material. AlₓTi₁₋ₓO_{y} may be an Al oxide (e.g., Al₂O₃) or a Ti oxide (TiO₂) according to the composition ratio (0≦x≦1, 1≦y≦2) of AlₓTi₁₋ₓO_{y}. AlₓTi₁₋ₓO_{y} may be manufactured in various shapes by various methods. For example, AlₓTi₁₋ₓO_{y} may be manufactured in bulk by chemical combination, or by sintering. Also, AlₓTi₁₋ₓO_{y} may be manufactured in thin film by sputtering, chemical vapor deposition (CVD), atomic layer deposition (ALD), plasma-enhanced atomic layer deposition (PE-ALD), a pulsed laser method, or an anodizing method.

A Ti or Al precursor of the thin-film type AlₓTi₁₋ₓO_{y} may be at least one compound selected from the group consisting of an organic metal compound including alkoxide and amine and an inorganic metal compound including halide and bromine (Br). An oxygen-precursor of the thin-film type AlₓTi₁₋ₓO_{y} may be one selected from the group consisting of oxygen (O), H₂O, hydrogen peroxide, and a mixture thereof. The temperature required to form the thin film may vary according to the type of the precursor required and the thin film manufacturing method used. That is, when an inorganic metal compound is used as the precursor, the forming temperature required increases. Also, the forming temperature required decreases when plasma is introduced.

Embodiments of the present invention provide a method of manufacturing an AlₓTi₁₋ₓO_{y} thin film using an ALD method. The ALD method is different from the general 1-x y chemical vapor deposition (CVD) method in that it uses a surface saturation reaction. In the ALD method, a thin film is deposited on an atomic layer basis. Even when a substrate has a rough surface or the structure formed in the substrate has a large aspect ratio, the ALD method makes it possible to manufacture a thin film that is generally uniform and has a stable composition. Also, even when the diameter of the substrate is 8 inches or more, the ALD method makes it possible to manufacture a thin film that is uniform and has a stable composition. However, as described above, the AlₓTi₁₋ₓO_{y} thin film may be may be formed using a variety of methods according to desired purpose of the thin film. In Embodiment 1, the AlₓTi₁₋ₓO_{y} thin film is manufactured using H₂O as an oxidizer. In Embodiment 2, the AlₓTi₁₋ₓO_{y} thin film is manufactured using an oxygen plasma that includes an inert gas. Embodiments of the present invention provide electric field devices using the AlₓTi₁₋ₓO_{y} thin film, as examples of application devices.

Manufacture of AlₓTi₁₋ₓO_{y} Thin Film

### EMBODIMENT 1

In order to form an AlₓTi₁₋ₓO_{y} thin film, a substrate is loaded into a reaction chamber. To form an Al oxide thin film, for example, an Al₂O₃ thin film, an Al-precursor is injected into the reaction chamber to form an absorption material on an upper surface of the substrate by surface saturation reaction. Thereafter, inert gas (e.g., nitrogen gas) is injected into the reaction chamber to remove any remaining unabsorbed precursor from the reaction chamber. An oxygen-precursor is injected into the reaction chamber to form a single layer of Al oxide by surface saturation reaction with the absorption material. Inert gas is injected into the reaction chamber to remove reaction byproducts remaining in the reaction chamber.

Thereafter, in order to form a Ti oxide thin film, for example, a TiO₂ thin film, a Ti-precursor is injected into the reaction chamber to form an absorption material on an upper surface of the substrate by surface saturation reaction. Thereafter, inert gas (e.g., nitrogen gas) is injected into the reaction chamber to remove any remaining unabsorbed precursor from the reaction chamber. An oxygen-precursor is injected into the reaction chamber to form a single layer of Ti oxide by surface saturation reaction with the absorption material. Inert gas is injected into the reaction chamber to remove reaction byproducts remaining in the reaction chamber.

The Al precursor used in the present embodiment may be at least one Al-based compound selected from the group consisting of an organic metal compound including alkoxide and amine and an inorganic metal compound including halide and bromine.

Trimethyl aluminum (TMA) is used as an organic metal precursor in the present embodiment. The Ti precursor used in the present embodiment may be at least one Ti-based compound selected from the group consisting of an organic metal compound including alkoxide and amine and an inorganic metal compound including halide and bromine. Titanium-tetra-isopropoxide (TTIP) is used as an organic metal precursor in the present embodiment. H₂O is used as the oxygen-precursor. The AlₓTi₁₋ₓO_{y} thin film may have a thickness of 10-10,000 nm, and preferably a thickness of 2-5,000 nm.

After removal of the reaction byproducts, the AlₓTi₁₋ₓO_{y} thin film may be heat-treated by an in-situ method. The heat treatment is performed to remove the defects of the AlₓTi₁₋ₓO_{y} thin film formed as described in the present embodiment. The heat treatment may be performed in the reaction chamber, or in another chamber that neighbors the reaction chamber and has the same environmental conditions as the reaction chamber.

In The present embodiment, the AlₓTi₁₋ₓO_{y} thin film is deposited in the composition ratio of 0≦x≦1 (preferably, 0.3≦x≦1) and 1≦y≦2. To this end, the Al oxide and the Ti oxide are deposited in the ratio of, for example, 1:1, 1:2, 1:3, 1:4, 1:5, 1:0 or 0:1. For the thin film formed in the ratio of 1:0 and 0:1, only the Al oxide or the Ti oxide are deposited respectively. When the thin film is manufactured in the above ratios, each layer is mixed with an atomic layer and a value of x varies.

The reaction chamber temperature may be such that the precursors maintain a vapor pressure necessary for the reaction. For example, the reaction chamber temperature may be set between room temperature and 450° C. In the present embodiment, a temperature of 100-300° C. is maintained according to the temperature required by the precursor used.

In order to form the AlₓTi₁₋ₓO_{y} thin film exhibiting MIT characteristics, the substrate can be formed using monocrystalline sapphire. However, the sapphire substrate is expensive and difficult to manufacture in a large diameter. Accordingly, the present invention uses a silicon substrate with a large diameter (e.g., 12 inches). In some cases, a glass or quartz substrate with a diameter of 8 inches or more may be used. In some cases, various materials such as a compound semiconductor may be used. Using glass and plastics creates reaction temperature limitations. Plastics can be used to form a flexible substrate.

### EMBODIMENT 2

Embodiment 2 is almost the same as the previous embodiment with the exception that the oxygen-precursor is converted into a plasma state.

The oxygen-precursor gas, for example comprised of oxygen and inert gas, is converted into a plasma state. The plasma state may be maintained for a predetermined time equal to or shorter than the injection time period of the oxygen-precursor in the previous embodiment. The plasma may be formed using a variety of methods. For example, an electric field can be directly applied to a reaction chamber directly exposing the surface of the absorption material to the plasma. Alternatively, the plasma oxygen-precursor gas is generated in a neighboring plasma chamber and is injected into the reaction chamber including the absorption material (a remote method). After removal of the reaction byproducts, the AlₓTi₁₋ₓO_{y} thin film may be heat-treated by an in-situ method. The heat treatment is performed to remove the defects of the AlₓTi₁₋ₓO_{y} thin film formed as described in the present embodiment. The heat treatment may be performed in the reaction chamber, or in another chamber that neighbors the reaction chamber and has the same environmental conditions as the reaction chamber.

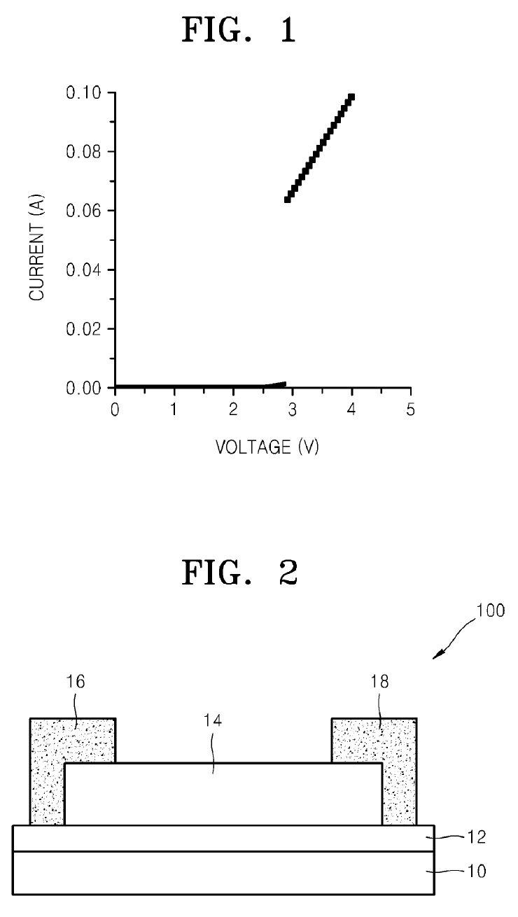

FIG. 1 is a graph illustrating a current-to-voltage relationship of an AlₓTi₁₋ₓO_{y} thin film according to an embodiment of the present invention.

Referring to FIG. 1, little current flows the AlₓTi₁₋ₓO_{y} thin film when a voltage applied to the AlₓTi₁₋ₓO_{y} thin film is about 3 V or less. Abrupt MIT occurs when the applied voltage is about 3V, and thus the current in the AlₓTi₁₋ₓO_{y} thin film abruptly increases. When the applied voltage is about 3V or more, the current-to-voltage relationship conforms to Ohm's law. This means that the AlₓTi₁₋ₓO_{y} thin film has transitioned into a metallic phase. The AlₓTi₁₋ₓO_{y} thin films according to previous and current embodiments of the present invention have an MIT voltage of about 3V at which the current in the AlₓTi₁₋ₓO_{y} thin film abruptly increases by a factor of 10-10,000. The MIT phenomenon repeatedly occurs even when the power is turned off and an electric field is re-applied.

The MIT of the AlₓTi₁₋ₓO_{y} thin film will now be described considering a temperature change. Thermal energy formed Q due to a temperature change at the time when a current is applied is given by the following equation.

Q=IVt=NCpΔT

Where I, V and t are current in the AlₓTi₁₋ₓO_{y} thin film, voltage applied to the AlₓTi₁₋ₓO_{y} thin film and time, respectively. N, Cp and ΔT are the number of moles, heat capacity and temperature change of the AlₓTi₁₋ₓO_{y} thin film, respectively. When the AlₓTi₁₋ₓO_{y} thin film was formed of a 1:1 mixture of Al₂O₃ and TiO₃, the current I, the voltage V and time T were respectively 0.7 mA, 3V and 670 μs. When substituting these values in the above equation, the thermal energy Q was found to be about 1.41×10⁻⁶ (J). Also, the heat capacity Cp 16.1 (cal/deg mol), that is, 67.6 (J/deg mol), and the number of moles was 4×10⁻¹⁰ (mol). At this time, the number of moles was measured according to the minimum volume of the AₓTi₁₋ₓO_{y} thin film when an electrode was formed. In the above conditions, the temperature change ΔT was calculated to be about 48° C.

In general, the melting point of Al₂O is 2,072° C., and the melting point of TiO₂ is 1830° C. That is, the above high temperature is required to change the Al₂O₃ and TiO₂ thin films into a molten state. However, the temperature change ΔT according to the embodiments of the present invention is considerably lower than the above temperature. Accordingly, the temperature change ΔT cannot cause a structural change of the AlₓTi₁₋ₓO_{y} thin film. Also, the AlₓTi₁₋ₓO_{y} thin film can be repeatedly transitioned into a metallic phase also when an electric field is repeatedly applied thereto. Therefore, it can be seen that the AlₓTi₁₋ₓO_{y} thin film does not undergo a structural change.

In general, Al₂O₃ has an energy band gap of about 8-9 eV and TiO₂ has an energy band gap of about 4-5 eV. In this regard, the AlₓTi₁₋ₓO_{y} thin film exhibits MIT even in a material with an energy band gap of 2 eV or more, preferable of 2-5 eV. When Al₂O₃ and TiO₂ are manufactured in the ratio of 1:4, Al₂O₃ has an energy band gap of about 3.2 eV and TiO₂ has an energy band gap of about 4.1 eV. This is differentiated from the conventional MIT material with an energy band gap of 2 eV or less. Accordingly, the number of materials applicable to application fields using MIT can be greatly increased.

Electric Field Devices using the AlₓTi₁₋ₓO_{y} Thin Film

The AlₓTi₁₋ₓO_{y} thin film with an energy band gap of 2 eV or more according to the embodiments of the present invention can be used to manufacture electric field devices that can form an electric field. These electric field devices will now be described in detail.

FIG. 2 is a cross-sectional view of a first switching device 100 using the AlₓTi₁₋ₓO_{y} thin film having an energy band gap of 2 eV or more, wherein the first switching device 100 is configured as a horizontal-structure two-terminal switching device, according to an embodiment of the present invention.

Referring to FIG. 2, an AlₓTi₁₋ₓO_{y} thin film 14 is formed on a substrate 10. The Alₓ Ti₁₋ₓO_{y} thin film 14 may be formed on a partial or entire upper surface of the substrate 10. A buffer layer 12 may be further formed between the substrate 10 and the AlₓTi₁₋ₓO_{y} thin film 14. Two electrodes (i.e., a first electrode 16 and a second electrode 18) are formed to contact the AlₓTi₁₋ₓO_{y} thin film 14.

The substrate 10 may be formed of monocrystalline sapphire, silicon, glass, quartz, compound semiconductors, or plastics, but the present invention is not limited to this. When glass or plastics form the substrate 10, reaction temperature limitations are created. The substrate 10 may be a flexible substrate if it is formed of a plastic. Silicon, glass, and quartz are preferable if the substrate 10 needs to have a diameter of 8 or more inches. To this end, the substrate 10 may be formed using a silicon-on-insulator (SOI).

The buffer layer 12 is used to enhance the crystallinity and adhesion of the AlₓTi₁₋ₓO_{y} thin film 14. To this end, the buffer layer 12 may be formed using a crystalline thin film with a similar lattice constant to the lattice constant of the AlₓTi₁₋ₓO_{y} thin film 14. For example, the buffer layer 12 may be formed using at least one of an aluminum oxide film, a high dielectric film, a crystalline metal film, and a silicon oxide film. At this time, the aluminum oxide film has only to maintain a predetermined crystallinity, and the silicon oxide film is preferably formed as thin as possible. Particularly, the buffer layer 12 may be formed of a film having a high dielectric constant and good crystallinity, such as a multi-layer film including a crystalline metal film and/or one selected from the group consisting of a TiO₂ film, a ZrO₂ film, a Ta₂O₅ film, a HfO₂ film, and a combination thereof.

The first and second electrodes 16 and 18 may be formed of a conductive material, but the present invention is not limited to this. For example, the first and second electrodes 16 and 18 may have at least one layer formed using one selected from the group consisting of Li, Be, C, Na, Mg, Al, K, Ca, Sc, Ti, V, Cr, Mn, Fe, Co, Ni, Cu, Zn, Ga, Rb, Sr, Y, Zr, Nb, Mo, Tc, Ru, Rh, Pd, Ag, Cd, In, Sn, Sb, Cs, Ba, La, Hf, Ta, W, Re, Os, Ir, Pt, Au, Hg, Pb, Bi, Po, Ce, Pr, Nd, Sm, Eu, Gd, Th, Dy, Ho, Er, Tm, Yb, Lu, Th, U, Np, Pu, a compound thereof, an oxide thereof, and an oxide of the compound. Here, examples of the compound are TiN and WN; an example of the oxide is ZnO; and examples of the oxide of the compound are In-tin oxide (ITO) and Al—Zn oxide (AZO).

The AlₓTi₁₋ₓO_{y} thin film 14 may be formed to a thickness of 10-10,000 nm. When a voltage is applied to the first and second electrodes 16 and 18, a current flows in a horizontal direction with respect to the substrate 10. When a critical voltage is applied to the AlₓTi₁₋ₓO_{y} thin film 14, the MIT occurs in the AlₓTi₁₋ₓO_{y} thin film 14 and the current responds to the applied voltage as illustrated in FIG. 1. The MIT temperature may vary according to a change in the thickness of the AlₓTi₁₋ₓO_{y} thin film 14.

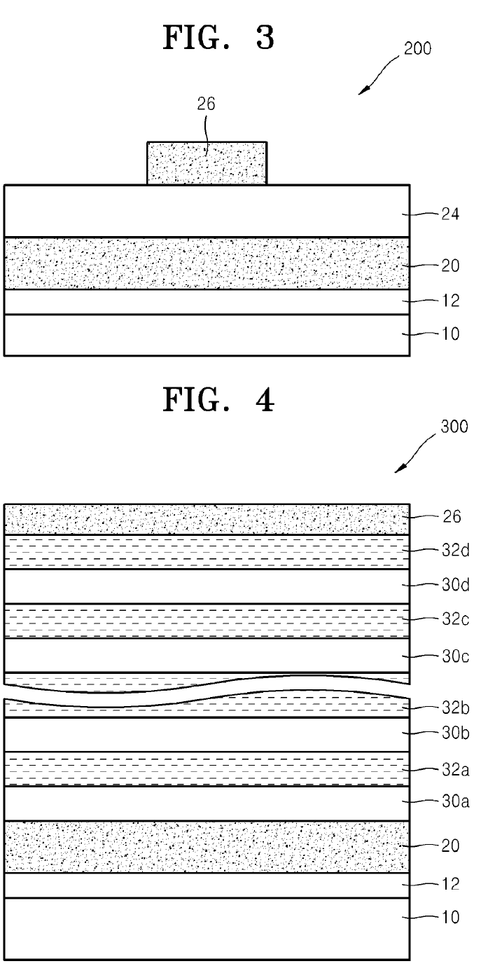

FIG. 3 is a cross-sectional view of a second switching device 200 using the AlₓTi₁₋ₓO_{y} thin film having an energy band gap of 2 eV or more wherein the second switching device 200 is configured as a vertical-structure two-terminal switching device, according to another embodiment of the present invention.

Referring to FIG. 3, a third electrode 20, an AlₓTi₁₋ₓO_{y} thin film 24, and a fourth electrode 26 are sequentially stacked on a substrate 10. The third electrode 20 is formed on a lower surface of the AlₓTi₁₋ₓO_{y} thin film 24, while the fourth electrode 26 is formed on an upper surface of the AlₓTi₁₋ₓO_{y} thin film 24. If necessary, a buffer layer 12 may be further formed between the substrate 10 and the third electrode 20.

The operation of the second switching device 200 is almost the same as that of the first switching device 100 of FIG. 2 with the exception that a current flows in a vertical direction with respect to the substrate 10 when the AlₓTi₁₋ₓO_{y} thin film 24 is transitioned into a metallic phase. The material type and the manufacturing method of the second switching device 200 are almost the same as those of the first switching device 100 with the exception of the stacking orientation of the third electrode 20, the AlₓTi₁₋ₓO_{y} thin film 24, and the fourth electrode 26.

FIG. 4 is a cross-sectional view of a third switching device 300 using the AlₓTi₁₋ₓO_{y} thin film having an energy band gap of 2 eV or more wherein the third switching device 300 is configured using a stack of devices similar to the second switching device 200 illustrated in FIG. 3, according to an embodiment of the present invention.

Referring to FIG. 4, a plurality of first MIT thin film layers 30a, 30b, 30c and 30d and a plurality of second MIT thin film layers 32a, 32b, 32c and 32d, which have an energy band gap of 2 eV or more, are alternately stacked between third and fourth electrodes 20 and 26 on a substrate 10. The first MIT thin film layers 30a, 30b, 30c and 30d may be formed of a Ti oxide, while the second MIT thin film layers 32a, 32b, 32c and 32d may be formed of an Al oxide. A buffer layer 12 may be further formed between the substrate 10 and the third electrode 20.

The thicknesses of the first and second MIT thin film layers 30 and 32 may be 1 nm through 1,000 nm. Each MIT thin film layer is deposited to a predetermined thickness. The first and second MIT thin film layers 30 and 32 are not mixed with each other but are independently formed and stacked.

The stacked thin film has larger density and refractivity than a single-layer thin film. Accordingly, it is possible to realize a stacked film with a reduced leakage current and an increased dielectric constant.

As described above, since the insulator undergoing the MIT does not undergo structural change, it can rapidly transition between a conductive phase (or a metal) and an insulative phase (or an insulator).

Also, since the insulator has an energy band gap of 2 eV or more, a larger number of materials can be used for the application fields which use the MIT.

Furthermore, limitless electric field devices using the insulator can be manufactured. Particularly, an electric field device with excellent physical properties can be realized by stacking the insulator undergoing the MIT in a multi-layer film.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. An insulator having an energy band gap of 2 eV or more and undergoing an abrupt metal-insulator transition, the insulator being abruptly changed from an insulator into a metal due to an energy change between electrons without undergoing a structural change.

2. The insulator of claim 1, wherein the energy change is caused by a change in temperature, pressure, and electric field externally applied.

3. The insulator of claim 1, wherein the insulator is one selected from the group consisting of an Al oxide, a Ti oxide, and an oxide of an Al—Ti alloy.

4. The insulator of claim 1, wherein the insulator is at least two selected from the group consisting of an Al oxide, a Ti oxide, an oxide of an Al—Ti alloy, and a combination thereof.

5. The insulator of claim 1, wherein the insulator is one selected from the group consisting of Al₂O₃, TiO₂, AlₓTi₁₋ₓO_{y} (0<x<1, 1≦y≦2), and a combination thereof.

6. The insulator of claim 1, wherein the energy band gap is between 2 eV and 5 eV.

7. A device comprising:
a substrate;
at least one layer of insulator thin film formed on the substrate, the insulator thin film having an energy band gap of 2 eV or more, undergoing an abrupt metal-insulator transition, and abruptly changing from an insulator into a metal by an energy change between electrons without undergoing a structural change; and
at least two electrodes spaced apart from each other and contacting the insulator thin film.

8. The device of claim 7, wherein the substrate comprises at least one layer formed of one selected from the group consisting of monocrystalline sapphire, silicon, SOI (silicon on insulator), glass, quartz, compound semiconductor, plastics, and an combination thereof.

9. The device of claim 7, further comprising a buffer layer disposed between the substrate and the insulator thin film.

10. The device of claim 7, wherein the electrodes each comprises at least one layer formed of conductive organic material or one selected from the group consisting of Li, Be, C, Na, Mg, Al, K, Ca, Sc, Ti, V, Cr, Mn, Fe, Co, Ni, Cu, Zn, Ga, Rb, Sr, Y, Zr, Nb, Mo, Tc, Ru, Rh, Pd, Ag, Cd, In, Sn, Sb, Cs, Ba, La, Hf, Ta, W, Re, Os, Ir, Pt, Au, Hg, Pb, Bi, Po, Ce, Pr, Nd, Sm, Eu, Gd, Tb, Dy, Ho, Er, Tm, Yb, Lu, Th, U, Np, Pu, a compound thereof, an oxide thereof, and an oxide of the compound.

11. The device of claim 10, wherein the compound is one of TiN and WN.

12. The device of claim 10, wherein the oxide of metal and the oxide of the compound is one of ITO (In-Tin oxide), AZO (Al—Zn oxide), or ZnO.

13. A method of manufacturing an insulator which undergoes an abrupt metal-insulator transition, the method comprising:
forming at least one layer of insulator which has an energy band gap of 2 eV or more, and abruptly changes from an insulator into a metal by an energy change between electrons without undergoing a structural change.

14. The method of claim 13, wherein the insulator is formed in bulk by chemical combination, or by sintering.

15. The method of claim 13, wherein the insulator is formed as a thin film by sputtering, chemical vapor deposition, atomic layer deposition, plasma-enhanced atomic layer deposition, a pulsed laser process, or an anodizing process.

16. The method of claim 13, wherein the insulator is formed as a thin film by atomic layer deposition or plasma-enhanced atomic layer deposition.

17. The method of claim 16, wherein an Al precursor used to form the Al oxide and the AlₓTi₁₋ₓO_{y} (0<x<1, 1≦y≦2) is at least one Al-based compound selected from the group consisting of an organic metal compound comprising alkoxide and amine and an inorganic metal compound comprising halide and bromine.

18. The method of claim 16, wherein a Ti precursor used to form the Ti oxide and the AlₓTi₁₋ₓO_{y} (0<x<1, 1≦y≦2) is at least one Ti-based compound selected from the group consisting of an organic metal compound comprising alkoxide and amine and an inorganic metal compound comprising halide and bromine.

19. The method of claim 16, wherein an oxygen-precursor used to form the Al oxide, the Ti oxide and the AlₓTi₁₋ₓO_{y} (0<x<1, 1≦y≦2) is one selected from the group consisting of oxygen, H₂O, hydrogen peroxide, and a mixture thereof.

20. The method of claim 16, wherein forming the Al oxide thin film comprises:
loading a substrate into a chamber;
injecting the Al precursor vapor into the chamber to form an absorption material on an upper surface of the substrate by surface saturation absorption;
purging the chamber to remove any remaining unabsorbed Al precursor vapor; and
injecting the oxygen-precursor into the chamber to form the Al oxide thin film by surface saturation reaction with the absorption material.

21. The method of claim 16, wherein forming the Ti oxide thin film comprises:
loading a substrate into a chamber;
injecting the Ti precursor vapor into the chamber to form an absorption material on an upper surface of the substrate by surface saturation absorption;
purging the chamber to remove any remaining unabsorbed Ti precursor vapor; and
injecting the oxygen-precursor into the chamber to form the Ti oxide thin film by surface saturation reaction with the absorption material.

22. The method of claim 16, wherein forming the AlₓTi₁₋ₓO_{y} (0<x<1, 1≦y≦2) thin film comprises:
loading a substrate into a chamber;
injecting the Al precursor vapor into the chamber to form a first absorption material on an upper surface of the substrate by surface saturation absorption;
purging the chamber to remove any remaining unabsorbed Al precursor vapor;
injecting the oxygen-precursor into the chamber to form the Al oxide thin film by surface saturation reaction with the first absorption material;
injecting the Ti precursor vapor into the chamber to form a second absorption material on an upper surface of the Al oxide thin film by surface saturation absorption;
purging the chamber to remove any remaining unabsorbed Ti precursor vapor; and
injecting the oxygen-precursor into the chamber to form the Ti oxide thin film by surface saturation reaction with the second absorption material,
wherein forming the Al oxide thin film and forming the Ti oxide thin film are repeatedly performed according to the composition ratio of the AlₓTi₁₋ₓO_{y} (0<x<1, 1≦y≦2) thin film.

23. The method of claim 22, wherein the ratio of the number of times of forming the Al oxide thin film to the number of times of forming the Ti oxide thin film is one of 1:1, 1:2, 1:3, 1:4, and 1:5.

24. The method of claim 22, wherein the oxygen-precursor is in a plasma state.

25. The method of claim 22, wherein the temperature of the chamber is between room temperature and 450° C.

26. The method of claim 16, wherein forming the AlₓTi₁₋ₓO_{y} (0<x<1, 1≦y≦2) thin film comprises:
loading a substrate into a chamber;
injecting the Al precursor vapor into the chamber to form a first absorption material on an upper surface of the substrate by surface saturation absorption;
purging the chamber to remove any remaining unabsorbed Al precursor vapor;
injecting the oxygen-precursor into the chamber and forming the Al oxide thin film with a thickness of 1-1,000 nm by repetition of surface saturation reaction with the first absorption material;
injecting the Ti precursor vapor into the chamber to form a second absorption material on an upper surface of the Al oxide thin film by surface saturation absorption;
purging the chamber to remove any remaining unabsorbed Ti precursor vapor; and
injecting the oxygen-precursor into the chamber and forming the Ti oxide thin film with a thickness of 1-1,000 nm by repetition of surface saturation reaction with the second absorption material,
wherein the Al oxide thin film and the Ti oxide thin film are alternately and repeatedly deposited.
